(19) United States
(12) Patent Application Publication
(10) Pub. No.: US 2025/0171889 A1
(43) Pub. Date: May 29, 2025

(54) FILM FORMING APPARATUS

(71) Applicant: SUMITOMO HEAVY INDUSTRIES, LTD., Tokyo (JP)

(72) Inventors: Yugo OKADA, Niihama-shi (JP); Makoto MAEHARA, Niihama-shi (JP); Kimio KINOSHITA, Niihama-shi (JP)

(21) Appl. No.: 18/959,678

(22) Filed: Nov. 26, 2024

(30) Foreign Application Priority Data
Nov. 28, 2023 (JP) 2023-201077

(51) Int. Cl. C23C 14/35

(52) U.S. Cl. CPC C23C 14/35

(57) ABSTRACT

A film forming apparatus for forming a film forming material on an object, includes: a chamber; a plasma gun that generates a plasma in the chamber; an anode on which the film forming material is allowed to be disposed in the chamber and that guides the plasma; and a magnetic field generating unit that generates a magnetic field in the chamber. The magnetic field generating unit causes the plasma to be incident on a surface of the film forming material by maintaining the magnetic field such that a zero magnetic field position at which the magnetic field becomes zero is at a predetermined position. The magnetic field generating unit has a directional component in a first direction in which the object and the film forming material face each other, and sets the zero magnetic field position such that the plasma is incident on the surface of the film forming material.

### CROSS-REFERENCE TO RELATED APPLICATIONS

This application claims priority to Japanese Patent Application No. 2023-201077, filed on Nov. 28, 2023, which is incorporated by reference herein in its entirety.

### BACKGROUND

### Technical Field

A certain embodiment of the present invention relates to a film forming apparatus.

### Description of Related Art

As a film forming apparatus, as in the related art, a film forming apparatus is known in which a film forming material is formed on an object by an ion plating method. This film forming apparatus generates a plasma in a chamber using a plasma gun to sublimate the film forming material in the chamber. The film forming material adheres to a substrate and is continuously deposited, whereby a film is grown and formed on the substrate.

### SUMMARY

According to an embodiment of the present invention, there is provided a film forming apparatus for forming a film forming material on an object using an RPD method, the film forming apparatus including: a chamber; a plasma gun that generates a plasma in the chamber; an anode on which the film forming material is allowed to be disposed in the chamber and that guides the plasma; and a magnetic field generating unit that generates a magnetic field in the chamber. The magnetic field generating unit causes the plasma to be incident on a surface of the film forming material by maintaining the magnetic field such that a zero magnetic field position at which the magnetic field in the chamber becomes zero is at a predetermined position. The magnetic field generating unit has a directional component in a first direction in which the object and the film forming material face each other, and sets the zero magnetic field position such that the plasma is incident on the surface of the film forming material.

### BRIEF DESCRIPTION OF THE DRAWINGS

FIG. 1 is a schematic cross-sectional view of a film forming apparatus according to an embodiment of the present invention.

FIG. 2 is a schematic view for describing a magnetic field in the film forming apparatus.

FIG. 3 is a schematic view showing an example of an incidence form of a plasma.

FIG. 4 is a schematic view showing an example of the incidence form of the plasma.

FIG. 5 is a schematic view showing an example of the incidence form of the plasma.

### DETAILED DESCRIPTION

Here, in the above-described film forming apparatus, it is required to form a high-quality film having a homogeneous film thickness. In order to form a high-quality film, it is required that the plasma is incident on a surface of the film forming material in an appropriate form.

It is desirable to provide a film forming apparatus capable of improving film quality.

In the film forming apparatus according to the embodiment of the present invention, the magnetic field generating unit causes the plasma to be incident on the surface of the film forming material by maintaining the magnetic field such that the zero magnetic field position at which the magnetic field in the chamber becomes zero is at a predetermined position. As described above, the magnetic field generating unit can provide an appropriate magnetic field configuration for causing the plasma to be incident on the surface of the film forming material by adjusting the zero magnetic field position to an appropriate position. The magnetic field generating unit has a directional component in the first direction in which the object and the film forming material face each other, and sets the zero magnetic field position such that the plasma is incident on the surface of the film forming material. Accordingly, the plasma can be incident in an appropriate incidence form for uniformly evaporating the film forming material. From the above, film quality of film formed on the object can be improved.

The magnetic field generating unit may set the zero magnetic field position such that the plasma is incident on an entire surface of the film forming material. Accordingly, the film forming material can be uniformly evaporated.

The magnetic field generating unit may include a ring hearth disposed around the anode. Accordingly, the magnetic field can be adjusted around the anode.

The magnetic field generating unit may set the zero magnetic field position at a position that is at or below a center axis of the plasma gun with respect to the surface of the film forming material in the first direction. In this case, it is possible to suppress excessive spreading of the plasma with respect to the film forming material.

The magnetic field generating unit may set the zero magnetic field position at a

position that is equal to or greater than a width dimension of the film forming material with respect to the surface of the film forming material in the first direction. In this case, a space for the plasma to spread over the film forming material can be secured, and the plasma can be suppressed from being incident on only a portion of the surface of the film forming material.

The magnetic field generating unit may set the zero magnetic field position at a position inside an inner periphery of the ring hearth on a plasma gun side with respect to a center axis of the film forming material in a second direction in which the center axis of the plasma gun extends. In this case, it is possible to suppress the plasma from being too biased toward the plasma gun side, and to suppress the plasma from being incident only on a portion of the surface of the film forming material.

The magnetic field generating unit may set the zero magnetic field position at a position inside an inner periphery of the anode on a side opposite to the plasma gun with respect to the center axis of the film forming material in the second direction in which the center axis of the plasma gun extends. In this case, it is possible to suppress the plasma from being excessively biased to the side opposite to the plasma gun and to suppress the plasma from being incident only on a portion of the surface of the film forming material.

The magnetic field generating unit may set the zero magnetic field position at a position where a distance from the surface of the film forming material in the first direction is 65 mm to 105 mm. In this case, a space for the plasma to spread over the film forming material can be secured, and the plasma can be suppressed from being incident on only a portion of the surface of the film forming material.

The magnetic field generating unit may set the zero magnetic field position at a position where a distance from the center axis of the film forming material toward the plasma gun side is 20 mm to 55 mm in the second direction in which the center axis of the plasma gun extends. In this case, it is possible to suppress the plasma from being too biased toward the plasma gun side, and to suppress the plasma from being incident only on a portion of the surface of the film forming material.

The magnetic field generating unit may further include at least one of an electrode of the plasma gun and a steering coil of the plasma gun. In this case, the magnetic field can be adjusted on the plasma gun side.

Hereinafter, a film forming method and a film forming apparatus according to an embodiment of the present invention will be described with reference to the accompanying drawings. In the description of the drawings, like elements are denoted by like reference symbols, and overlapping descriptions will be omitted.

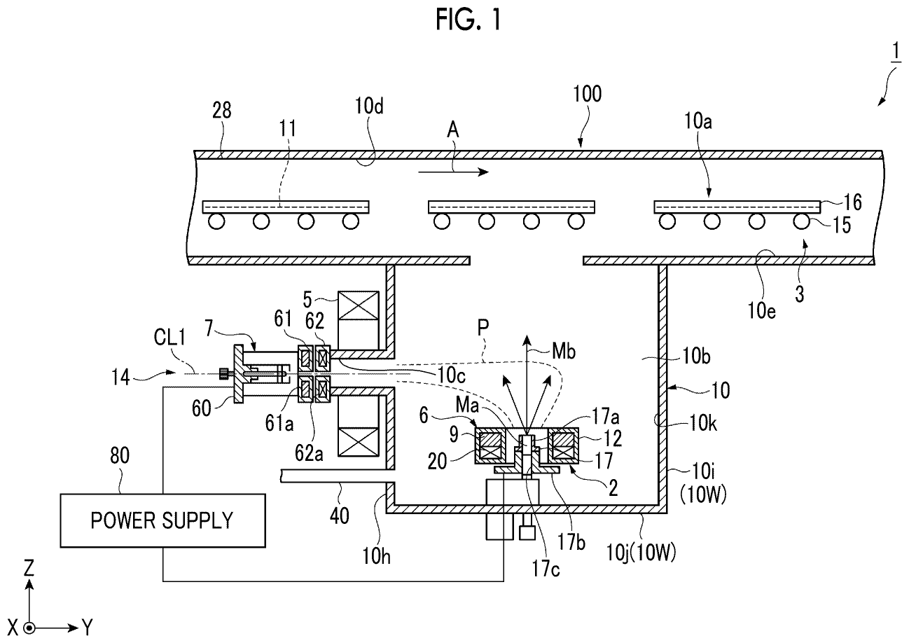

First, a configuration of the film forming apparatus according to the embodiment of the present invention will be described with reference to FIG. 1. FIG. 1 is a schematic cross-sectional view showing a configuration of a film forming apparatus 1. As shown in FIG. 1, the film forming apparatus 1 of the present embodiment is a reactive plasma deposition (RPD) film forming apparatus used for an RPD method, which is a type of so-called ion plating method. A feature of the RPD method is that a high-density plasma generated by using a plasma gun 7 is introduced into a film forming material Ma by a hearth mechanism 2, thereby allowing sublimation of a material and ionization of particles of the sublimated material to be performed by the same mechanism. Since the RPD method uses a high-density plasma, an ionization rate of the material particles is high, and a thin film having higher density and stronger adhesion to a substrate can be formed compared to a general ion plating method. For convenience of description, FIG. 1 shows an XYZ coordinate system. A Y-axis direction is a direction in which a center axis of the plasma gun 7 extends. A Z-axis direction is a position where the substrate and a hearth mechanism, which will be described later, face each other. An X-axis direction is a direction perpendicular to the Y-axis direction and the Z-axis direction.

The film forming apparatus 1 may be a so-called horizontal type film forming apparatus in which a substrate 11 is disposed and transported in a chamber 10 such that a sheet thickness direction of the substrate 11 (object) is substantially a vertical direction. In this case, the X-axis and Y-axis directions are horizontal directions, and the Z-axis direction is the vertical direction and the sheet thickness direction. The film forming apparatus 1 may also be a so-called vertical film forming apparatus in which the substrate 11 is disposed and transported in the chamber 10 in a state where the substrate 11 is placed upright or inclined from the upright state such that the sheet thickness direction of the substrate 11 is the horizontal direction (Z-axis direction in FIG. 1). In this case, the Z-axis direction is the horizontal direction and the sheet thickness direction of the substrate 11, the Y-axis direction is the horizontal direction, and the X-axis direction is the vertical direction. The film forming apparatus according to the embodiment of the present invention will be described below by taking a horizontal film forming apparatus as an example.

The film forming apparatus 1 includes the chamber 10 (chamber), a transport mechanism 3, and a film forming mechanism 14.

The chamber 10 is a member for accommodating the substrate 11 and performing a film forming process. The chamber 10 includes a transport chamber 10a for transporting the substrate 11 on which a film of a film forming material Ma is to be formed, a film forming chamber 10b for diffusing the film forming material Ma, and a plasma port 10c through which a plasma P irradiated from the plasma gun 7 in a beam form is received by the chamber 10. The transport chamber 10a, the film forming chamber 10b, and the plasma port 10c communicate with each other. The transport chamber 10a is set along a predetermined transport direction (arrow A in the figure) (along a Y-axis). The chamber 10 is made of a conductive material and is connected to a ground potential.

The film forming chamber 10b includes, as a wall portion 10W, a pair of side walls along the transport direction (arrow A), a pair of side walls 10h and 10i along the direction (Z-axis direction) intersecting the transport direction (arrow A), and a bottom wall 10j disposed intersecting the X-axis direction.

The transport mechanism 3 transports a substrate holding member 16 that holds the substrate 11 in a state of facing the film forming material Ma in the transport direction (arrow A). For example, the substrate holding member 16 is a frame body that holds an outer peripheral edge of the substrate 11. The transport mechanism 3 is constituted by a plurality of transporting rollers 15 installed in the transport chamber 10a. The transport rollers 15 are arranged at equal intervals along the transport direction (arrow A), and transport the substrate holding member 16 in the transport direction (arrow A) while supporting the substrate holding member 16. As the substrate 11, a plate-shaped member such as a glass substrate or a plastic substrate is used.

Subsequently, a configuration of the film forming mechanism 14 will be described in detail. The film forming mechanism 14 causes particles generated as a result of the sublimation of the film forming material Ma by the ion plating method to adhere to the substrate 11. The film forming mechanism 14 includes the plasma gun 7, a steering coil 5, a hearth mechanism 2, and a ring hearth 6.

The plasma gun 7 is, for example, a pressure gradient type plasma gun, and has a main body portion connected to the film forming chamber 10b through the plasma port 10c provided in the side wall of the film forming chamber 10b. The plasma gun 7 generates the plasma P in the chamber 10. The plasma P generated in the plasma gun 7 is emitted in a beam form from the plasma port 10c into the film forming chamber 10b. Accordingly, the plasma P is generated in the film forming chamber 10b.

The plasma gun 7 generates a plasma by discharging electricity into an argon gas introduced through a cathode 60. A first intermediate electrode (grid) 61 and a second intermediate electrode (grid) 62 are concentrically arranged between the cathode 60 and the plasma port 10c. An annular permanent magnet 61a for converging the plasma P is embedded in the first intermediate electrode 61. An electromagnet coil 62a is also embedded in the second intermediate electrode 62 to converge the plasma P. In the present embodiment, the first intermediate electrode 61 is disposed on a cathode 60 side with respect to the second intermediate electrode 62. However, a positional relationship may be reversed. The steering coil 5 is provided around the plasma port 10c to which the plasma gun 7 is attached. The steering coil 5 guides the plasma P into the film forming chamber 10b. The steering coil 5 is excited by causing a current to flow therethrough by a power source (not shown) for the steering coil.

The hearth mechanism 2 holds the film forming material Ma. The hearth mechanism 2 is provided in the film forming chamber 10b of the vacuum chamber 10 and is disposed in a negative direction in the Z-axis direction when viewed from the transport mechanism 3. The hearth mechanism 2 includes a main hearth 17 that is a main anode that guides the plasma P emitted from the plasma gun 7 to the film forming material Ma or a main anode that guides the plasma P emitted from the plasma gun 7 to itself. A configuration of the main hearth will be described later.

The ring hearth 6 is an auxiliary anode having an electromagnet for inducing the plasma P. The ring hearth 6 is disposed around a container 17a of the main hearth 17 that holds the film forming material Ma. The ring hearth 6 includes an annular coil 9, an annular permanent magnet portion 20, and an annular container 12, and the coil 9 and the permanent magnet portion 20 are accommodated in the container 12. In the present embodiment, the permanent magnet portion 20 and the coil 9 are installed in this order in a negative Z direction when viewed from the transport mechanism 3, but the coil 9 and the permanent magnet portion 20 may be installed in this order in the negative Z direction. The ring hearth 6 controls a direction of the plasma P incident on the film forming material Ma or a direction of the plasma P incident on the main hearth 17, according to a magnitude of a current flowing through the coil 20.

A gas supply unit 40 supplies a carrier gas and an oxygen gas into the chamber 10. As a substance contained in the carrier gas, for example, a rare gas such as argon or helium is adopted. The gas supply unit 40 is disposed outside the chamber 10, and supplies a raw material gas into the chamber 10 through a gas supply port provided in the side wall (for example, the side wall 10h) of the film forming chamber 10b. The gas supply unit 40 supplies the carrier gas and the oxygen gas at flow rates based on a control signal from a control unit 90.

A power supply 80 supplies a current to the plasma gun 7. Accordingly, the plasma gun 7 performs discharging with a discharge current having a predetermined value. The power supply 80 is connected to the plasma gun 7 serving as a cathode and the main hearth 17 serving as an anode. The power supply 80 supplies a current having a current value based on a control signal from the control unit 90. The control unit 90 is a device that controls the entire film forming apparatus 1.

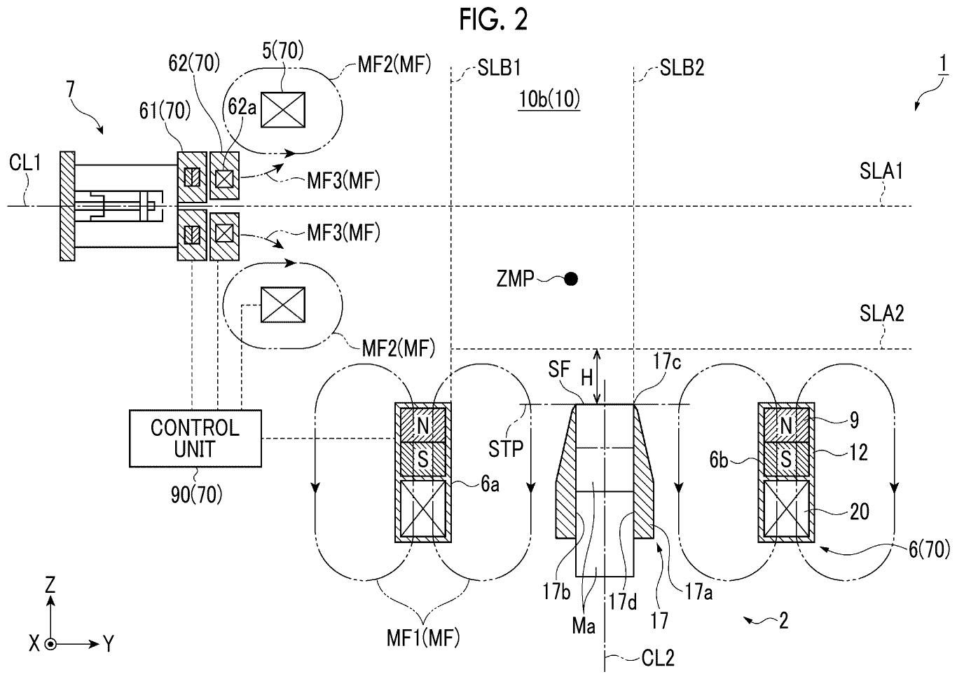

Next, a configuration of the main hearth 17 will be described in detail with reference to FIG. 2. The main hearth 17 is capable of sublimating the film forming material Ma. The main hearth 17 includes the tubular container 17a extending in a positive direction in the Z-axis direction and filled with the film forming material Ma. The main hearth 17 is maintained at a positive potential with respect to the ground potential of the chamber 10. Therefore, the main hearth 17 serves as an electrode (anode) in a discharge and can attract the plasma P. A through-hole 17b through which the film forming material Ma is filled is formed in the container 17a of the main hearth 17 on which the plasma P is incident. A surface SF of a tip portion of the film forming material Ma is exposed to the film forming chamber 10b (see FIG. 1) at one end of the through-hole 17b.

As the film forming material Ma, for example, a conductive material such as tin-doped indium oxide (ITO) and tungsten-doped indium oxide (IWO) is used. In a case where the film forming material Ma is made of a conductive material, when the main hearth 17 is irradiated with the plasma P, the plasma P is directly incident on the film forming material Ma, the surface SF of the tip portion of the film forming material Ma is heated and sublimated, and film forming material particles Mb ionized by the plasma P diffuse into the film forming chamber 10b (see FIG. 1). The film forming material particles Mb diffused in the film forming chamber 10b are ionized by the plasma P, move in a positive Z-axis direction in the film forming chamber 10b, and adhere to a surface of the substrate 11 in the transport chamber 10a (see FIG. 1). The film forming material Ma is a solid material formed into a cylindrical shape having a predetermined length, and the hearth mechanism 2 is filled with a plurality of film forming materials Ma at one time. Then, the film forming material Ma is sequentially extruded from a negative Z direction side of the hearth mechanism 2 in accordance with the sublimation of the film forming material Ma such that the tip portion of the film forming material Ma on a foremost side maintains a predetermined positional relationship with an upper end part of the main hearth 17 to achieve a constant film forming (sublimation) rate.

The film forming material Ma may be, for example, an insulating material such as silicon oxide or tin oxide. In a case where the film forming material Ma is made of an insulating material, the plasma P is incident into an upper end portion 17c of the main hearth 17. Accordingly, the main hearth 17 is heated, so that the film forming material Ma is heated and sublimated.

As shown in FIG. 2, the film forming apparatus 1 includes a magnetic field generating unit 70. The magnetic field generating unit 70 is a unit for generating a magnetic field MF in the chamber 10. In the present embodiment, the magnetic field generating unit 70 includes the ring hearth 6, the steering coil 5 of the plasma gun 7, the electrodes 61 and 62 of the plasma gun 7, and the control unit 90. The ring hearth 6 generates a magnetic field MF1 in the vicinity of the main hearth 17 and the film forming material Ma. The magnetic field MF1 spreads in a diffusing manner from an end portion of the ring hearth 6 on a positive side in the Z-axis direction toward the positive side in the Z-axis direction. The steering coil 5 generates a magnetic field MF2. The magnetic field MF2 spreads in a diffusing manner from an inner peripheral side around the steering coil 5 toward a positive side in the Y-axis direction. The electrodes 61 and 62 generate a magnetic field MF3. The magnetic field MF3 spreads in a diffusing manner from a tip end side of the plasma gun 7 toward the positive side in the Y-axis direction. The magnetic field generating unit 70 generates the magnetic field MF (cusp magnetic field) that adjusts a distribution of the plasma P by a combination of the magnetic fields MF1, MF2, and MF3. The control unit 90 controls the magnetic fields MF1, MF2, and MF3 by controlling the currents supplied to the coil 20 of the ring hearth 6, the steering coil 5, and the coil 62a of the second intermediate electrode 62. Therefore, the control unit 90 can control the magnetic field MF by controlling the currents respectively supplied to the coils 20, 5, and 62a.

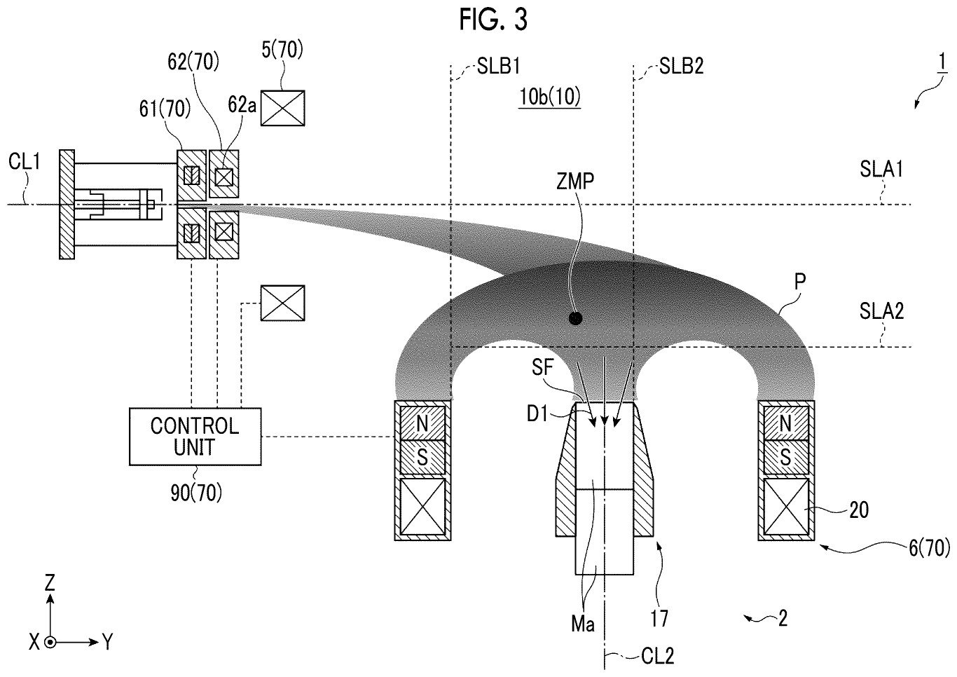

The magnetic field generating unit 70 causes the plasma P to be incident on the surface SF of the film forming material Ma by maintaining the magnetic field MF such that a zero magnetic field position ZMP at which the magnetic field MF in the chamber 10 becomes zero is at a predetermined position (see FIGS. 3 to 5). The plasma P is emitted from the plasma gun 7, and is incident on the surface SF of the film forming material Ma and an end surface of the ring hearth 6 on the positive side in the Z-axis direction. However, at the zero magnetic field position ZMP, no magnetic flux extends in any direction in a three-dimensional direction. A method for specifying the zero magnetic field position ZMP is not particularly limited. For example, the zero magnetic field position ZMP can be specified by specifying a brightest point of the plasma P based on an image of the plasma P (or using a sensor or the like). In addition, the zero magnetic field position ZMP can be specified by measuring an inside of the chamber 10 with a gauss meter.

The magnetic field generating unit 70 can maintain the position of the zero magnetic field position ZMP constant by maintaining a generation form of the magnetic field MF. That is, the position of the zero magnetic field position ZMP changes in response to a change in distribution of a magnetic flux of the magnetic field MF. Therefore, when the magnetic field generating unit 70 maintains the distribution of the magnetic flux of the magnetic field MF at a certain distribution, the zero magnetic field position ZMP is also maintained at a certain position. Specifically, the control unit 90 can maintain the zero magnetic field position ZMP constant by maintaining the current value for each of the coils 20, 5, and 62a at a constant value. A behavior of the plasma P in the chamber 10 changes in response to the change in the distribution of the magnetic flux of the magnetic field MF, and an incidence form of the plasma P on the surface SF of the film forming material Ma also changes. For this reason, there is a correlation between the position of the zero magnetic field position ZMP and the incidence form of the plasma P on the surface SF. The incidence form of the plasma P on the surface SF is determined, for example, by an incident direction of the plasma P on the surface SF and a range of incidence of the plasma P on the surface SF.

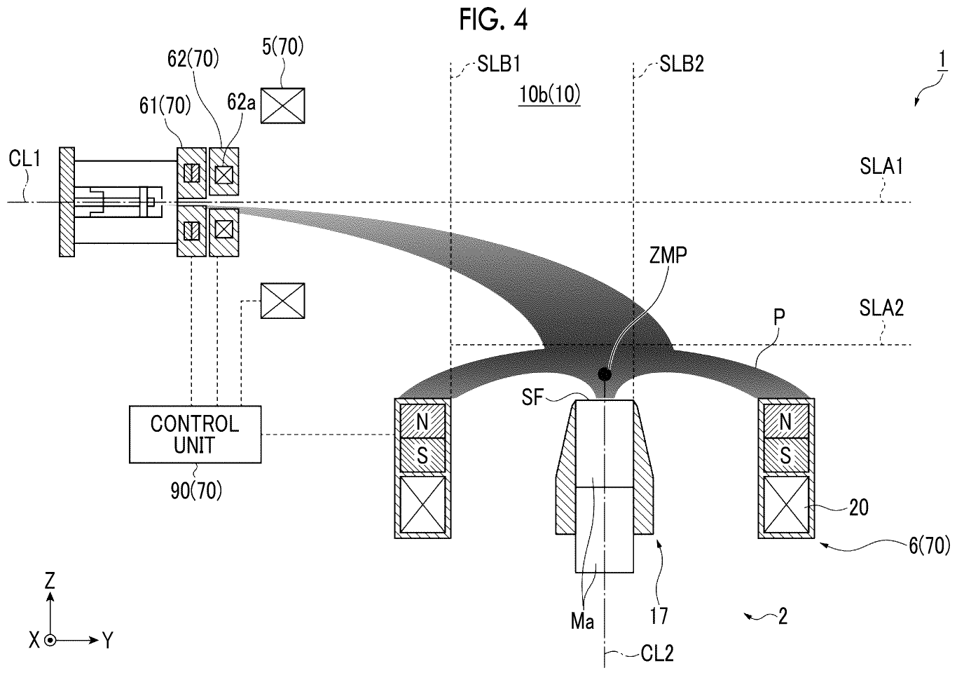

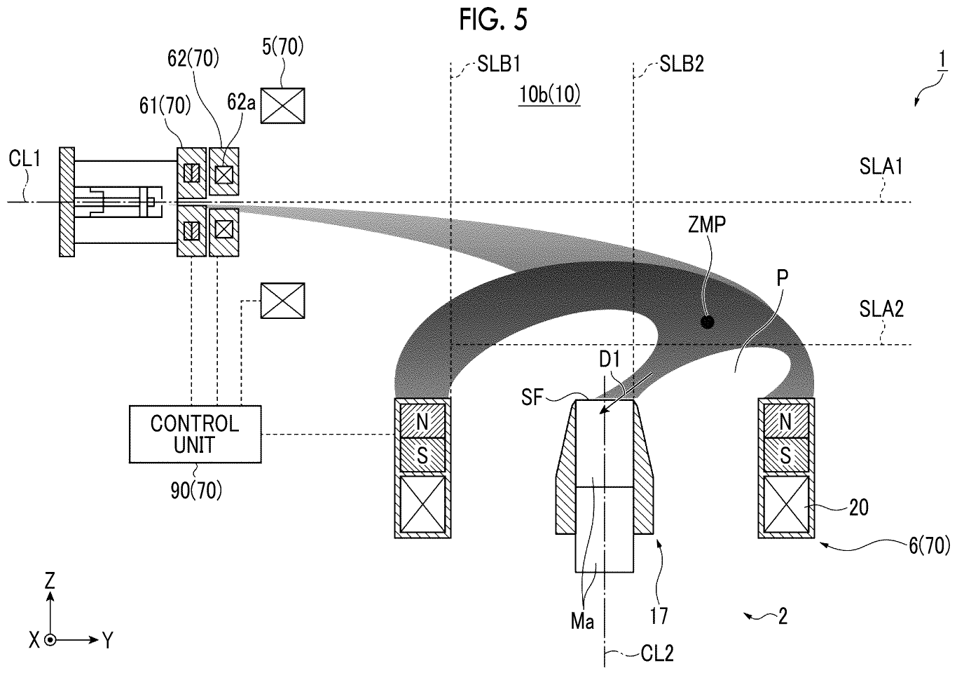

As shown in FIG. 3, the magnetic field generating unit 70 has a directional component in the Z-axis direction (first direction), which is a direction in which the substrate 11 (see FIG. 1) and the film forming material Ma face each other, and sets the zero magnetic field position ZMP such that the plasma P is incident on the surface SF of the film forming material Ma. The plasma P is incident on the surface SF of the film forming material Ma in a plurality of incident directions D1. However, the incident directions D1 have directional components directed from the positive side to a negative side in the Z-axis direction. In examples shown in FIGS. 3 and 4, the incident directions D1 are substantially parallel to the Z-axis direction. On the other hand, in an example shown in FIG. 5, the incident direction D1 has an incident direction D1 that is mainly inclined with respect to the Z-axis direction.

The magnetic field generating unit 70 may set the zero magnetic field position ZMP such that the plasma P is incident on the entire surface SF of the film forming material Ma. In the example shown in FIG. 3, an end surface of the film forming material Ma on the positive side in the Z-axis direction is exposed from the main hearth 17 on an inner peripheral side of the main hearth 17. In this way, an entire region of the exposed surface SF from an edge portion on an outer peripheral side to a central position is covered with the plasma P. This situation is that the plasma P is incident on the entire surface SF of the film forming material Ma. On the other hand, in the examples shown in FIGS. 4 and 5, there is a portion of the surface SF that is not covered with the plasma P. This situation does not correspond to a case where the plasma P is incident on the entire surface SF of the film forming material Ma.

Next, a suitable position for setting the zero magnetic field position ZMP will be described with reference to FIG. 2. In the following description, the position of the zero magnetic field position ZMP will be described when viewed in a direction (here, the X-axis direction) perpendicular to a center axis CL1 of the plasma gun 7 and a center axis CL2 of the main hearth 17 as shown in FIGS. 2 to 5. In a case where positions of the center axis CL1 and the center axis CL2 in the X-axis direction are the same, the position of the zero magnetic field position ZMP in the X-axis direction is set to the same position as the center axis CL1 and the center axis CL2. In a case where the positions of the center axis CL1 and the center axis CL2 in the X-axis direction are different from each other, the position of the zero magnetic field position ZMP in the X-axis direction is set at a position between the center axis CL1 and the center axis CL2.

The magnetic field generating unit 70 may set the zero magnetic field position ZMP at a position that is at or below the center axis CL1 of the plasma gun 7 in the Z-axis direction with respect to the surface SF of the film forming material Ma. A reference line SLA1 extending in the Y-axis direction is set at the position of the center axis CL1 of the plasma gun 7. In this case, the zero magnetic field position ZMP is set on the reference line SLA1 or at a position on the negative side in the Z-axis direction with respect to the reference line SLA1.

The magnetic field generating unit 70 may set the zero magnetic field position ZMP at a position that is equal to or greater than a width dimension H of the film forming material Ma with respect to the surface SF of the film forming material Ma in the Z-axis direction. A reference line SLA2 parallel to the Y-axis direction is set at a position separated from the surface SF by the width dimension H in the Z-axis direction. In this case, the zero magnetic field position ZMP is set on the reference line SLA2 or at a position on the positive side in the Z-axis direction with respect to the reference line SLA2. In the present embodiment, the surface SF of the film forming material Ma is extruded so as to always be constant. The surface SF may not always be constant. In this case, a reference position STP, which serves as a reference on the negative side in the Z-axis direction when a range of the width dimension H is defined, may be set on the surface SF of the film forming material Ma when film formation starts. In this case, even in a case where the position of the surface SF of the film forming material Ma moves downward due to evaporation, the reference position STP remains constant. Alternatively, the reference position STP may be set at a position of the upper end portion 17c of the main hearth 17 on the positive side in the Z-axis direction.

The magnetic field generating unit 70 may set the zero magnetic field position ZMP at a position inside an inner periphery of the ring hearth 6 on a plasma gun 7 side with respect to the center axis CL2 of the film forming material Ma in the Y-axis direction (second direction) in which the center axis CL1 of the plasma gun 7 extends. A reference line SLB1 extending in the Z-axis direction is set at a position of the inner periphery of the ring hearth 6 at a position of an end portion 6a on the plasma gun 7 side (negative side in the Y-axis direction). In this case, the zero magnetic field position ZMP is set on the reference line SLB1 or at a position on the positive side in the Y-axis direction with respect to the reference line SLB1.

The magnetic field generating unit 70 may set the zero magnetic field position ZMP at a position inside an inner periphery of the main hearth 17 on a side opposite to the plasma gun 7 with respect to the center axis CL2 of the film forming material Ma in the Y-axis direction in which the center axis CL1 of the plasma gun 7 extends. A reference line SLB2 extending in the Z-axis direction is set at a position of the inner periphery of the ring hearth 6 at a position of the end portion 17d on the side opposite to the plasma gun 7 side (the positive side in the Y-axis direction). In this case, the zero magnetic field position ZMP is set on the reference line SLB2 or at a position on the negative side in the Y-axis direction with respect to the reference line SLB2.

Next, the position of the zero magnetic field position ZMP and the form of the plasma P will be described with reference to FIGS. 3 to 5. In the example shown in FIG. 3, the zero magnetic field position ZMP is set at a position between the reference line SLA1 and the reference line SLA2 in the Z-axis direction. The zero magnetic field position ZMP is set at a position between the reference line SLB1 and the reference line SLB2 in the Y-axis direction. In this case, the plasma P can sufficiently spread before reaching the film forming material Ma. As a result, the plasma P is incident on the entire surface SF of the film forming material Ma.

In the example shown in FIG. 4, the zero magnetic field position ZMP is set at a position on the negative side in the Z-axis direction with respect to the reference line SLA2 in the Z-axis direction. The zero magnetic field position ZMP is set at a position between the reference line SLB1 and the reference line SLB2 in the Y-axis direction. In this case, the plasma P cannot sufficiently spread before reaching the film forming material Ma. As a result, the plasma P is incident on a partial range of the surface SF of the film forming material Ma, instead of the entire surface SF.

In the example shown in FIG. 5, the zero magnetic field position ZMP is set at a position between the reference line SLA1 and the reference line SLA2 in the Z-axis direction. The zero magnetic field position ZMP is set at a position on the positive side in the Y-axis direction with respect to the reference line SLB2 in the Y-axis direction. In this case, the plasma P is incident on the film forming material Ma in a state of being biased to the positive side in the Y-axis direction. The plasma P is incident on the surface SF of the film forming material Ma in a state of being inclined obliquely. As a result, the plasma P is incident on a partial range of the surface SF of the film forming material Ma, instead of the entire surface SF

Next, a suitable range of the zero magnetic field position ZMP will be described based on a simulation result of the film formation. As a result of intensive research conducted by the inventors of the present invention, it was found that a range of a current at which the plasma P is incident on the surface of the film forming material Ma and a transparent conductive film with low resistance and high transparency can be formed is “10A to 20A” for the steering coil 5 and “20A to 40A” for the ring hearth 6. A film formation simulation was conducted based on the range of current values. In this case, the magnetic field formed in the chamber 10 was calculated. Conditions of the simulation other than the coil current in this case are as follows. A size of the chamber 10 was set to “X: 610 mm×Y: 500 mm×Z: 560 mm”.

A distance from the center axis CL2 of the film forming material Ma to the zero magnetic field position ZMP on the plasma gun 7 side in the Y-axis direction is defined as “Y”. A distance from the surface SF of the film forming material Ma in the Z-axis direction is defined as “Z”. In a case where “Condition 1” was set to “steering coil current: 20 A, ring hearth current: 20 A, the results were “Z: 70.2 mm, Y: 38.0 mm”. In a case where “Condition 2” was set to “steering coil current: 15 A, ring hearth current: 25 A, the results were “Z: 79.8 mm, Y: 38.6 mm”. In a case where “Condition 3” was set to “steering coil current: 10 A, ring hearth current: 40 A, the results were “Z: 98.1 mm, Y: 49.8 mm”. Under “Condition 1”, the zero magnetic field position ZMP is closest to a film forming material Ma side. Under “Condition 3”, the zero magnetic field position ZMP is closest to the plasma gun 7 side. From the result, it was found that it is appropriate to set “Y” to a range of 38.0 mm to 49.8 mm and “Z” to a range of 70.2 mm to 98.1 mm as the range of the zero magnetic field position ZMP.

In an actual machine of the film forming apparatus 1, in order to adjust the incident position of the plasma P, it was found that it is appropriate to set “Y” to a range of 20 mm to 55 mm and “Z” to a range of 65 mm to 105 mm as the range of the zero magnetic field position ZMP in consideration of deviations from the simulation model described above. The current range of each coil is not limited to the current range in the simulation described above, and the zero magnetic field position ZMP can be set within the range of the reference lines SLA1, SLA2, SLB1, and SLB2 described in FIGS. 2 to 5 by adjusting the current to a range outside the current range.

Next, the operation and effects of the film forming apparatus 1 according to the present embodiment will be described.

In the film forming apparatus 1 according to the present embodiment, the magnetic field generating unit 70 causes the plasma P to be incident on the surface SF of the film forming material Ma by maintaining the magnetic field MF such that the zero magnetic field position ZMP at which the magnetic field MF in the chamber 10 becomes zero is at a predetermined position. As described above, the magnetic field generating unit 70 can provide an appropriate magnetic field configuration for causing the plasma P to be incident on the surface SF of the film forming material Ma by adjusting the zero magnetic field position ZMP to an appropriate position. The magnetic field generating unit 70 has a directional component in the Z-axis direction in which the substrate 11 and the film forming material Ma face each other, and sets the zero magnetic field position ZMP such that the plasma P is incident on the surface SF of the film forming material Ma. Accordingly, the plasma P can be incident in an appropriate incidence form for uniformly evaporating the film forming material Ma. From the above, film quality of the film formed on the substrate 11 can be improved. In addition, electrical characteristics, optical characteristics, and the like can be improved depending on the material of the film.

The magnetic field generating unit 70 may set the zero magnetic field position ZMP such that the plasma P is incident on the entire surface SF of the film forming material Ma. Accordingly, the film forming material Ma can be uniformly evaporated.

The magnetic field generating unit 70 may include the ring hearth 6 disposed around the main hearth 17. Accordingly, the magnetic field MF can be adjusted around the main hearth 17.

The magnetic field generating unit 70 may set the zero magnetic field position ZMP at a position that is at or below the center axis CL1 of the plasma gun 7 in the Z-axis direction with respect to the surface SF of the film forming material Ma. In this case, it is possible to suppress excessive spreading of the plasma P with respect to the film forming material Ma.

The magnetic field generating unit 70 may set the zero magnetic field position ZMP at a position that is equal to or greater than the width dimension H of the film forming material Ma with respect to the surface SF of the film forming material Ma in the Z-axis direction. In this case, a space for the plasma P to spread over the film forming material Ma can be secured, and the plasma P can be suppressed from being incident on only a portion of the surface SF of the film forming material Ma.

The magnetic field generating unit 70 may set the zero magnetic field position ZMP at a position inside the inner periphery of the ring hearth 6 on the plasma gun 7 side with respect to the center axis CL2 of the film forming material Ma in the Y-axis direction (second direction) in which the center axis CL1 of the plasma gun 7 extends. In this case, it is possible to suppress the plasma P from being too biased toward the plasma gun 7 side, and to suppress the plasma P from being incident only on a portion of the surface SF of the film forming material Ma.

The magnetic field generating unit 70 may set the zero magnetic field position ZMP at a position inside the inner periphery of the main hearth 17 on the side opposite to the plasma gun 7 with respect to the center axis CL2 of the film forming material Ma in the Y-axis direction in which the center axis CL1 of the plasma gun 7 extends. In this case, it is possible to suppress the plasma P from being excessively biased to the side opposite to the plasma gun 7 and to suppress the plasma P from being incident only on a portion of the surface SF of the film forming material Ma.

The magnetic field generating unit 70 may set the zero magnetic field position ZMP at a position where the distance from the surface SF of the film forming material Ma in the Z-axis direction is 65 mm to 105 mm. In this case, a space for the plasma P to spread over the film forming material Ma can be secured, and the plasma P can be suppressed from being incident on only a portion of the surface SF of the film forming material Ma.

The magnetic field generating unit 70 may set the zero magnetic field position ZMP at a position where the distance from the center axis CL2 of the film forming material Ma toward the plasma gun 7 side is 20 mm to 55 mm in the Y-axis direction in which the center axis CL1 of the plasma gun 7 extends. In this case, it is possible to suppress the plasma P from being too biased toward the plasma gun 7 side, and to suppress the plasma P from being incident only on a portion of the surface SF of the film forming material Ma.

The magnetic field generating unit 70 may further include at least one of the electrodes 61 and 62 of the plasma gun 7 and the steering coil 5 of the plasma gun 7. In this case, the magnetic field MF can be adjusted on the plasma gun 7 side.

Here, in the present embodiment, as a mechanism for disposing the substrate 11, a mechanism for continuously transporting the substrate 11 (continuous film formation type) is adopted. In such a continuous film formation type, the film is formed while the substrate 11 is flowed in a plasma emission direction of the plasma gun 7. Since the film tends to be distributed in the emission direction of the plasma P, it is preferable to flow the substrate 11 in the emission direction. In the continuous film formation type, compared to a film forming apparatus according to a comparative example (a case where the zero magnetic field position ZMP is outside the predetermined range), a direction of a film thickness distribution to be homogenized is a direction (X-axis direction) intersecting the direction in which the substrate 11 is flowed. The mechanism for disposing the substrate 11 is not limited to the continuous film formation type, and may be a batch type in which the substrate 11 is disposed in the chamber 10 each time.

In a case where the film forming material Ma is an insulating material, the plasma P is incident on a tip part of the main hearth 17. However, by setting the zero magnetic field position ZMP to the range of the reference lines SLA1, SLA2, SLB1, and SLB2, the plasma P can be suitably incident on the entire tip part of the main hearth 17.

The present invention is not limited to the above-described embodiment of the film forming apparatus.

The position, size, direction, angle, and the like of each component of the film forming apparatus described above may be appropriately changed without departing from the concept of the present invention. For example, an emission direction of the plasma gun 7 may not be parallel to the Y-axis, and may be inclined. The magnetic field generating unit does not need to include all of the ring hearth, the electrodes of the plasma gun, and the steering coil, and some of these may be omitted.

It should be understood that the invention is not limited to the above-described embodiment, but may be modified into various forms on the basis of the spirit of the invention. Additionally, the modifications are included in the scope of the invention.

What is claimed is:

1. A film forming apparatus for forming a film forming material on an object using an RPD method, the film forming apparatus comprising:
a chamber;
a plasma gun that generates a plasma in the chamber;
an anode on which the film forming material is allowed to be disposed in the chamber and that guides the plasma; and
a magnetic field generating unit that generates a magnetic field in the chamber,
wherein the magnetic field generating unit causes the plasma to be incident on a surface of the film forming material by maintaining the magnetic field such that a zero magnetic field position at which the magnetic field in the chamber becomes zero is at a predetermined position, and
the magnetic field generating unit has a directional component in a first direction in which the object and the film forming material face each other, and sets the zero magnetic field position such that the plasma is incident on the surface of the film forming material.

2. The film forming apparatus according to claim 1,
wherein the magnetic field generating unit sets the zero magnetic field position such that the plasma is incident on an entire surface of the film forming material.

3. The film forming apparatus according to claim 1,
wherein the magnetic field generating unit includes a ring hearth disposed around the anode.

4. The film forming apparatus according to claim 3,
wherein the ring hearth is an auxiliary anode having an electromagnet for inducing a plasma, and is disposed around a container of the anode that holds the film forming material.

5. The film forming apparatus according to claim 4,
wherein the ring hearth includes an annular coil, an annular permanent magnet portion, and an annular container,
the annular coil and the annular permanent magnet portion are accommodated in the annular container, and
the annular permanent magnet portion and the annular coil are installed in this order in a negative Z direction when viewed from a transport mechanism, or the annular coil and the annular permanent magnet portion are installed in this order in the negative Z direction.

6. The film forming apparatus according to claim 5,
wherein the ring hearth controls a direction of the plasma incident on the film forming material or a direction of the plasma incident on the anode according to a magnitude of a current flowing through the annular coil.

7. The film forming apparatus according to claim 1, further comprising:
a gas supply unit that supplies a carrier gas and an oxygen gas at flow rates based on a control signal from a control unit into the chamber.

8. The film forming apparatus according to claim 7,
wherein the gas supply unit is disposed outside the chamber, and supplies a raw material gas into the chamber through a gas supply port provided in a side wall of a film forming chamber.

9. The film forming apparatus according to claim 1,
wherein the magnetic field generating unit sets the zero magnetic field position at a position that is at or below a center axis of the plasma gun with respect to the surface of the film forming material in the first direction.

10. The film forming apparatus according to claim 1,
wherein the magnetic field generating unit sets the zero magnetic field position at a position that is equal to or greater than a width dimension of the film forming material with respect to the surface of the film forming material in the first direction.

11. The film forming apparatus according to claim 1,
wherein the magnetic field generating unit sets the zero magnetic field position at a position inside an inner periphery of a ring hearth on a plasma gun side with respect to a center axis of the film forming material in a second direction in which a center axis of the plasma gun extends.

12. The film forming apparatus according to claim 1,
wherein the magnetic field generating unit sets the zero magnetic field position at a position inside an inner periphery of the anode on a side opposite to the plasma gun with respect to a center axis of the film forming material in a second direction in which a center axis of the plasma gun extends.

13. The film forming apparatus according to claim 1,
wherein the magnetic field generating unit sets the zero magnetic field position at a position where a distance from the surface of the film forming material in the first direction is 65 mm to 105 mm.

14. The film forming apparatus according to claim 1,
wherein the magnetic field generating unit sets the zero magnetic field position at a position where a distance from a center axis of the film forming material toward a plasma gun side is 20 mm to 55 mm in a second direction in which a center axis of the plasma gun extends.

15. The film forming apparatus according to claim 3,
wherein the magnetic field generating unit further includes at least one of an electrode of the plasma gun and a steering coil of the plasma gun.

16. The film forming apparatus according to claim 15,
wherein the magnetic field generating unit is capable of adjusting a magnetic field on a plasma gun side.
